(19) United States
(12) Patent Application Publication
(10) Pub. No.: US 2006/0261820 A1
(43) Pub. Date: Nov. 23, 2006

(54) Providing power from a power source to a power sink

(76) Inventor: Steven R. Bard, Vancouver, WA (US)

Correspondence Address: TROP PRUNER & HU, PC, 1616 S. VOSS ROAD, SUITE 750, HOUSTON, TX, 77057-2631, US

(21) Appl. No.: 11/399,710

(22) Filed: Apr. 6, 2006

Related U.S. Application Data
(63) Continuation of application No. 09/619,219, filed on Jul. 19, 2000.

(51) Int. Cl. G01R 31/00

(52) U.S. Cl. 324/508

(57) ABSTRACT

A communication between a power source and a power sink determines whether the source can supply the power needs of a given sink. This determination may be based not only on the capacity of the source but also on the number of sinks already coupled to a given source. Thus, the source may be adaptable to varying power needs of coupled sinks of varying numbers.

This application is a continuation of U.S. patent application Ser. No. 09/619,219, filed on Jul. 19, 2000.

### BACKGROUND

This invention relates generally to the provision of power from a power source to a power sink and in particular embodiments to the provision of power to a battery operated device.

A wide variety of electronic devices receive power from a power source. For example, a mobile computer system such as a laptop computer may receive power from an AC adapter sometimes called a brick. Generally, each mobile computer system uses its own separate brick that provides a conversion from AC power to a DC voltage and current level that meet the requirements of a particular mobile computer system. Thus, each mobile computer system is sold with a particular AC adapter, increasing the overall cost of each mobile computer system.

It would be desirable to provide a power source that is capable of providing power to a plurality of devices. However, providing such a source risks the possibility that too many power sinks may be coupled to the power source. Overloading the source may cause the power source to fail or to provide less than the required power to one or more of the devices.

Moreover, it would be desirable to enable power sinks to couple to a power source with some degree of assurance that, despite the fact that the power source was not supplied with the system, the power source can be depended upon to supply the required power levels.

### BRIEF DESCRIPTION OF THE DRAWINGS

FIG. 1 is a schematic depiction of one embodiment of the present invention;

FIG. 2 is a schematic depiction of an embodiment of the present invention involving a mobile computer system and an AC adapter;

FIG. 3 is a flow chart for software for the power source of a power source/sink pair in accordance with one embodiment of the present invention; and

FIG. 4 is a flow chart for software for a sink of a power source/sink pair.

### DETAILED DESCRIPTION

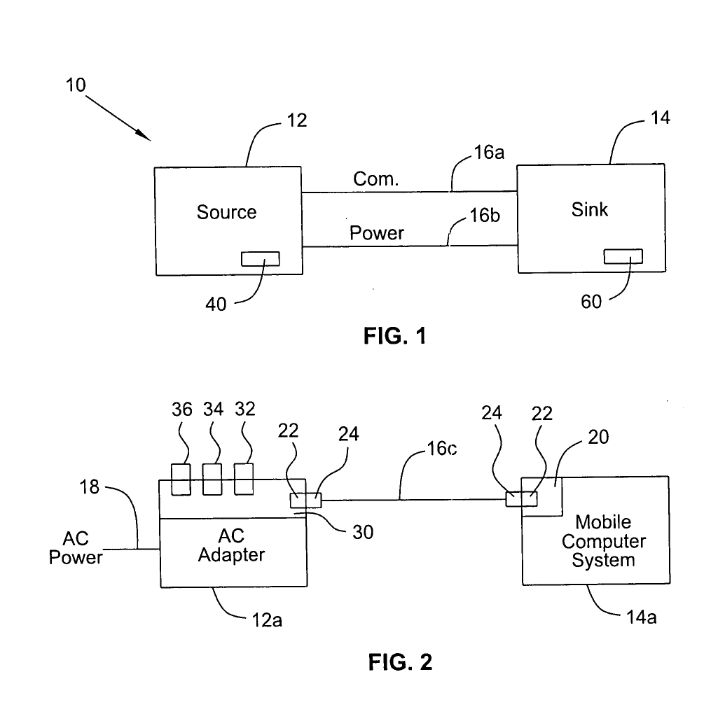

A system 10 may include a power source 12 and the power sink 14 coupled by a power supplying link or connection 16b and a communication link 16a, as shown in FIG. 1. In some embodiments a single cable or link may supply both power and communication channels. The source 12 may supply power over the link 16b and may exchange information with the sink 14 over the link 16a.

A power source is any device capable of providing a source of power to a power sink. A power source may be fixed in that it supplies a specific voltage level at a specific amperage level. A power source may be dynamic in that it has the capability of altering either or both of its voltage level or current capacity. A power sink is any device that consumes energy provided by a power source. A physical connection between the power source and the power sink includes a delivery mechanism for power to the sink and a communication medium between the two.

In loosely coupled connection between the sink 14 and the source 12, the source 12 may provide a specific signal to the sink 14 for example through a reserved pin on a link 16a. The sink 14, upon detecting the signal, may determine that it may charge its internal battery from the power available from the source 12.

In a tightly coupled system, more complex communications may be possible between the source 12 and the sink 14. In such case, a communication protocol implemented by firmware or software residing on the sink 14 may make certain decisions about the amount and use of power provided by the source 12. In one embodiment, the sink 14 may determine whether the source 12 is a valid source from which the sink 14 may charge its internal battery. Thus, a tightly coupled connection between the sink 14 and source 12 may utilize a higher level of communication over the link 16a. However, a higher level of communication may not be necessary for the sink 14 to detect that the source 12 is a device from which the sink 14 may charge its internal battery. A lower level of detection may be used for this purpose, such as the loosely coupled connection described previously.

Referring next to FIG. 2, not only may a tightly or loosely coupled connection be implemented between the source 12a and the sink 14a, but moreover, a given source 12a may provide power to a plurality of sinks. Thus, in the example shown in FIG. 2, the source 12a may be an AC adapter and the sink 14 may be a mobile computer system 14a. A link 16 with plugs 24 and sockets 22 provides connections between the sink 14a and the source 12a. Particularly, a plug 24a plugs into a socket 22a on the sink 14a and a plug 24b plugs into a socket 22b on the source 12a. The source 12a is coupled to a source of AC power indicated at 18.

A fan out unit 30 may receive the plug 24b in its socket 22b. However, the fan out unit 30 may also supply power through a plurality of sockets 32, 34 and 36, each capable of communicating with an additional power sink (not shown). Thus, in one example, the source 12a may power both the sink 14a and other related devices such as a cellular phone, a printer, a display device, and the like.

The source 12a may determine seriatim for each connected sink whether the source 12a has the available power resources to supply the power needs of each subsequently coupled sink. Each time a new sink is connected, the source 12a may undertake a communication protocol with the coupled sink to establish what its power needs are and to determine whether the source 12a can meet those power needs.

In one embodiment of the present invention, the source 12a may be implemented in accordance with the IEEE 1394b standard, preliminary draft P1394b, Revision 1.0, dated Feb. 25, 2000 available from the Institute of Electrical and Electronics Engineers (IEEE), Inc., 35 E. 47th Street, New York, N.Y. 10017. In addition, a 1394b beta socket, plug pair may be utilized, since an extra pin is available in these socket/plug pairs.

The source 12a may be a fan out physical layer or FOP. A FOP is a multi-ported physical layer that is attached to a physical layer integrated with a link layer (PIL) via a serial interface. A physical layer is a serial bus protocol layer that translates logical symbols used by the link layer into electrical signals on a serial bus medium. The physical layer is self-initializing. Physical layer arbitration guarantees that only one node at a time is sending data.

A link layer is the serial bus protocol layer that provides confirmed and unconfirmed transmission or reception of primary packets. A primary packet is any packet that is not an acknowledgement or a physical layer packet. A primary packet is an integral number of quadlets and contains a transaction code in the first quadlet. A quadlet is four bytes or thirty-two bits of data.

Thus, the sink 14a may include a 1394b physical layer integrated within a link (PIL). A PIL is a link that uses a modified beta port to attach to a FOP using the protocol defined in the 1394b standard. A beta port is a port that operates according to the specifications of the IEEE 1394b standard.

A self-ID packet is a physical layer packet that provides information about a device that transmits the self-ID packet including, for example, the device's identity, its location and its power requirements. A self-ID packet is provided, for example, from the sink 14a to the source 12a. If the source 12a includes a processor-based system such as a controller in its FOP 30, the source 12a may determine whether or not to provide the requested power.

For example, under the 1394b protocol, a primary power provider is a node that reports its power class as either one, two or three in its first self-ID packet. This type of device provides fifteen, thirty or forty-five watts to the power connection 16b. Thus, a serial bus connection may be provided between the PIL (sink 14a) and the FOP (source 12a) in which the FOP selectively supplies up to four coupled sinks. The FOP may provide power according to a pre-established routine. However, other non-1394b embodiments may also be used.

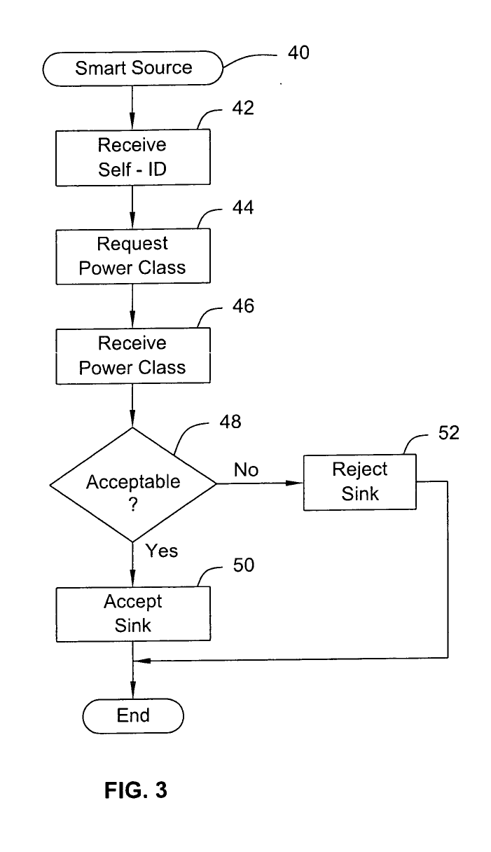

Referring to FIG. 3, in one embodiment, the software or firmware 40 for implementing the source 12 begins by receiving the self-ID packet from a given requesting sink 14, as indicated in block 42. The source 12 may include a processor-based system such as a microcontroller, an embedded controller or a processor. At this stage, the source 12 may also have one or more connected sinks 14. As indicated in block 46, the source 12 may then receive a power class request from the sink 14. A given sink may request a power class, in accordance with one embodiment of the present invention, as indicated in block 44. This request may be in the form of a specific request for a given power class, in terms of voltage and current for example. Alternatively, the request may be simply an identifier which identifies the sink 14. The source 12 may then make a determination, based on the identifier for the sink 14, about what power class the sink needs.

If the power class requested by the sink 14 is acceptable, given the available resources of the source 12, as determined in diamond 48, the sink 14 may be given an acknowledge signal indicating that the sink 14 may receive power from the source 12, as indicated in block 50. In one case, the power class requested from the sink 14 may be such that it enables the sink 14 to receive sufficient power to charge its battery. In other cases, the sink 14 may be acknowledged for its ongoing power needs but the source 12 may be unable to supply sufficient power to enable the sink 14 to charge its battery. If the needed power class is unavailable from the source 12, for example because of the capabilities of the source 12 or the number of power consuming sinks already coupled to the source 12, the source 12 may reject the sink as indicated in block 52.

In each case, in accordance for example with the 1394b protocol, any coupled sink 14 receives sufficient power for enumeration. Thus, the protocol indicated in FIG. 3 may be accomplished with power supplied from the source 12 or from an available link 16 regardless of whether the source 12 ultimately can supply the ongoing working power needs of a given sink 14.

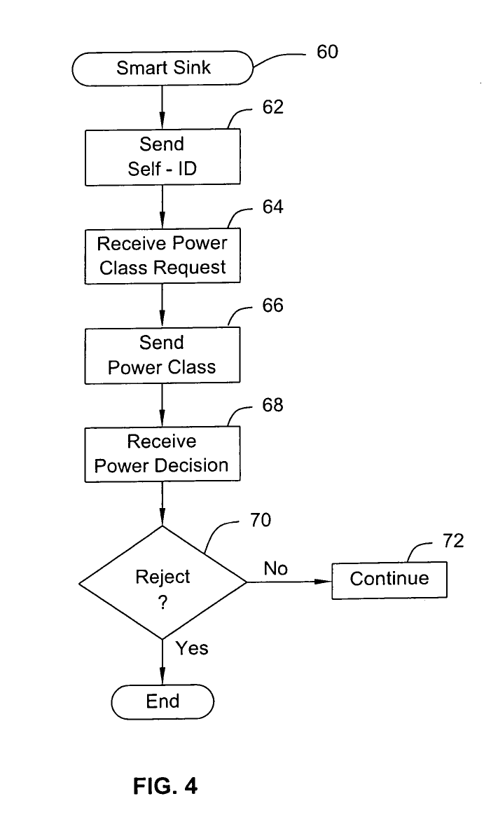

Referring next to FIG. 4, the software 60 resident on a processor-based sink 14, begins by sending a self-ID packet as indicated in block 62 in one embodiment of the invention. The present invention is not in any way limited to the 1394b protocol. In general, a self-ID packet may be a non-1394b identifier or may be the self-ID packet described in the 1394b protocol.

The sink 14 then receives a power class request from the source 12 as indicated in block 64. The sink 14 may send its power class request as indicated in block 66. When the sink 14 receives a power decision from the source 12, as indicated in block 68, the sink 14 determines whether the decision is to reject or accept the sink 14 as determined at diamond 70. If the sink 14 is not rejected, the sink 14 continues to operate through the source 12 as indicated in block 72.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
detecting a coupling of a power sink to a power source;
automatically receiving a signal in said sink; and
using said signal in said power sink to determine in said sink whether to receive power from said power source.

2. The method of claim 1 including detecting the coupling of a plurality of power sinks to the power source and sending a data signal between the source and each sink to determine whether the source can provide power to each sink.

3. The method of claim 1 including receiving a self-identifier packet in the sink.

4. The method of claim 2 including determining the available power of the source based on the power requirements of a particular sink.

5. The method of claim 2 including determining whether to supply power to a given sink based on the power requirements of any sinks already coupled to said source and the power capacity of said source.

6. The method of claim 2 including supplying sufficient power for enumeration to a sink coupled to said source.

7. The method of claim 6 wherein if the source is unable to supply power to the sink, refusing to supply power to said sink except for enumeration.

8. The method of claim 1 including sending an identifier to said source that is used by the source to determine whether the source can supply power to said sink.

9. A machine readable medium having instructions that when executed cause a machine to:
detect the coupling of a power source to said system;
receive a signal in said system; and
use said signal in said system to determine whether to receive power from said source.

10. The machine readable medium of claim 9 further having instructions that when executed cause a machine to detect a coupling of a plurality of power sinks to the power source and send the data signal between the source and each sink to determine whether the source can provide power to each sink.

11. The machine readable medium of claim 9 further having instructions that when executed cause a machine to receive a self-identifier packet from the sink.

12. The machine readable medium of claim 9 further having instructions that when executed cause a machine to receive a power class indication from the sink.

13. The machine readable medium of claim 9 further having instructions that when executed cause a machine to determine its available power based on the power requirements of a sink.

14. The machine readable medium of claim 9 further having instructions that when executed cause a machine to determine whether to supply power to a given sink based on the power requirements of sinks already coupled to the source and the power capacity of said source.

15. The machine readable medium of claim 10 further having instructions that when executed cause a machine to supply sufficient power for enumeration to any sink coupled to said source.

16. The machine readable medium of claim 15 further having instructions that when executed cause a machine, if the source is unable to apply power to the sink, to refuse to supply power to the sink except for enumeration.

17. The machine readable medium of claim 9 further having instructions that when executed cause a machine to use an identifier from a sink to determine whether the source can supply power to the sink.

18. A system comprising:
a connection to a source of power; and
a processor-based device to analyze a signal received from a power source and automatically determine whether to receive power from said power source.

19. The system of claim 18 wherein said system includes a fan out physical layer.

20. The system of claim 18 wherein said system includes an AC adapter.

21. The system of claim 18 wherein said processor-based device determines whether to provide power to a power consuming device that is connected to said system.

22. The system of claim 18 wherein said system provides power to the power consuming device for enumeration and then determines whether to provide additional power to said power consuming device.
